(19) United States
(12) Patent Application Publication
(10) Pub. No.: US 2023/0301074 A1
(43) Pub. Date: Sep. 21, 2023

(54) PROGRAMMABLE READ-ONLY MEMORY

(71) Applicant: STMicroelectronics (Rousset) SAS, Rousset (FR)

(72) Inventors: Patrick Calenzo, Peypin (FR); Sandra Mattei, Fuveau (FR)

(21) Appl. No.: 18/186,499

(22) Filed: Mar. 20, 2023

(30) Foreign Application Priority Data
Mar. 21, 2022 (FR) 2202466

(51) Int. Cl. H10B 20/25

(52) U.S. Cl. CPC H10B 20/25

(57) ABSTRACT

A memory cell is disclosed. In an embodiment a programmable read-only memory cell includes a first insulating layer located between a semiconductor body and a second conductive or semi-conductive layer, wherein the first insulating layer comprises a peripheral portion and a central portion, and wherein the peripheral portion has a greater thickness than the central portion.

### CROSS-REFERENCE TO RELATED APPLICATIONS

This application claims the benefit of French Application No. 2202466, filed on Mar. 21, 2022, which application is hereby incorporated herein by reference.

### TECHNICAL FIELD

The present disclosure generally concerns memory cells and more precisely memory cells of programmable read-only memory type.

### BACKGROUND

A programmable read-only memory (PROM, or OTP for One Time Programmable) is a type of read-only memory that can be programmed only once.

There are a plurality of different types of programmable read-only memories including a type called fusible, corresponding to memory cells where an insulating layer is damaged by an electric breakdown. The memory cell thus contains a first binary value when the insulator is not damaged and another binary value when the insulator is damaged.

### SUMMARY

Embodiments overcome disadvantages of known programmable read-only memories.

Embodiments provide a programmable read-only memory comprising a first insulating layer located between a semiconductor body and a second conductor or semiconductor layer, the first insulating layer comprising a peripheral portion and a central portion, the peripheral portion having a thickness greater than the thickness of the central portion.

According to an embodiment, the body is in contact with the first layer and the second layer is in contact with the first layer.

According to an embodiment, the body and the second layer are not in contact.

According to an embodiment, the thicknesses of the central and peripheral portions of the first layer are substantially constant.

According to an embodiment, the thickness of the peripheral portion of the first layer is at least one and a half time greater than the central portion of the first layer.

According to an embodiment, the body comprises first and second regions, the second region being more heavily doped than the first region, the central portion being in contact with the second region.

According to an embodiment, the second region surrounds a portion of the first region, the central portion only resting on the second region and on said portion of the first region.

According to an embodiment, a peripheral portion of the second region is covered with the peripheral portion.

According to an embodiment, the portion of the second region which is not covered with the central portion is covered with the peripheral portion.

According to an embodiment, the dopant concentration of the second region is at least twice greater than that of the first region.

According to an embodiment, the smallest dimension, in the plane of the upper surface of the body, of the portion of the central portion of the first layer located opposite the second region is at least equal to 0.5 μm.

According to an embodiment, the body comprises a third region, more heavily doped than the second region, surrounding the second region and comprising at least a portion which is not covered with the first layer.

According to an embodiment, the cell comprises at least one conductive contact in contact with the third region.

According to an embodiment, the ratio between the width of the peripheral portion and the central portion is greater than or equal to 2.

According to an embodiment, the second layer only covers the first layer.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an embodiment of a memory cell of a programmable read-only memory;

FIG. 2 shows a view of the embodiment of FIG. 1 in plane B-B of FIG. 1; and

FIG. 3 is a view of the embodiment of FIG. 1 in plane B-B of FIG. 1.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

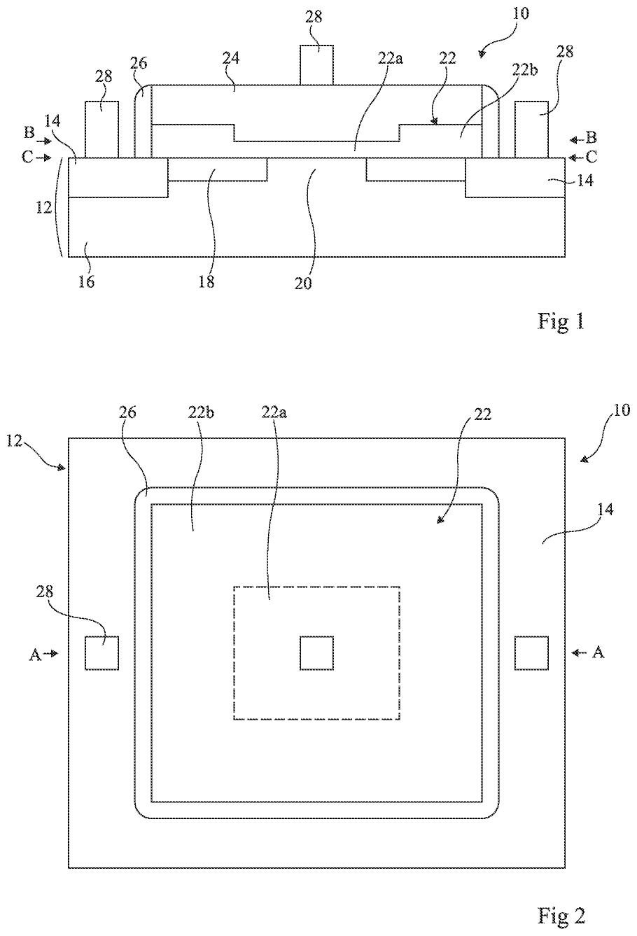

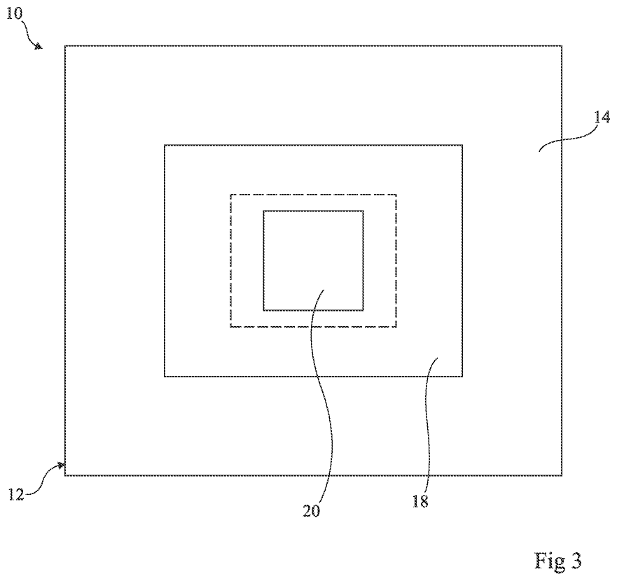

FIG. 1 shows an embodiment of a memory cell 10 of a programmable read-only memory. FIG. 2 shows a view of the embodiment of FIG. 1 along plane B-B of FIG. 1. FIG. 1 is a cross-section view of the memory cell 10 of a programmable read-only memory along plane A-A of FIG. 2. FIG. 3 is a view in plane C-C of FIG. 1.

Cell 10 is formed inside and on top of a body 12. Body 12 is made of a semiconductor material, for example, of silicon. Body 12 is doped with a first conductivity type, for example, type N. Body 12 is, for example, in a solid substrate, for example, doped with a same conductivity type as body 12. As a variant, body 12 is formed in a substrate of semiconductor-on-insulator type (SOI).

Body 12 comprises a region 14. Region 14 is a heavily-doped region of the first conductivity type. In other words, region 12 is a doped region of the same doping type as body 12. The height of region 14 is smaller than the height of body 12. Region 14 is flush with an upper surface of body 12. FIG. 3 corresponds to a view in the plane of the upper surface of body 12. Region 14 is thus visible therein.

Region 14 rests on a region 16 of the body. Region 14 is more heavily doped than region 16. For example, the dopant concentration in region 14 is at least ten times greater than the dopant concentration in region 16. Region 14 is located in the entire periphery of body 12. Region 14 thus forms a closed contour.

Body 12 comprises a region 18. Region 18 is a doped region of the same conductivity type as region 14 and region 16. Region 18 is more heavily doped than region 16, for example, at least twice more heavily doped. In other words, the dopant concentration in region 18 is at least twice greater than the dopant concentration in region 16. Region 18 is for example less heavily doped than region 14.

Region 18 is flush with the upper surface of body 12. Region 18 has a thickness smaller than the thickness of region 14. Region 18 rests on region 16.

Region 18 is located inside of the contour formed by region 14. Region 18 is thus surrounded with region 14. Region 18 is in lateral contact with region 14. For example, the contact, or interface, between regions 14 and 18 entirely surrounds region 18.

Region 18 for example surrounds a region 20. Region 20 is flush with the upper surface of body 12. Region 20 is a portion of region 16 and is preferably in contact with the portions of region 16 having regions 14 and 18 resting thereon. Region 20 is more heavily-doped than regions 14 and 18. For example, region 20 is at least twice less heavily doped than region 18. In other words, the dopant concentration of region 20 is smaller, for example, at least twice smaller, than the dopant concentration of region 18. The dopant concentration of region 20 is for example substantially equal to the dopant concentration of the rest of region 16.

Memory cell 10 comprises an insulating layer 22, For example, made of an oxide, for example, of silicon oxide. Layer 22 rests on body 12. Layer 22 entirely covers region 20. Layer 22 covers at least partially, preferably entirely, region 18. Layer 22 for example partially covers region 14.

Layer 22 comprises a first portion, or central portion, 22a and a second portion, or peripheral portion, 22b. Layer 22 preferably only comprises the first and second portions. The separation between portions 22a and 22b is represented in dotted lines in FIGS. 2 and 3. Portion 22a is surrounded, preferably entirely, by portion 22b in a plane parallel to the upper surface of body 12.

Portion 22a has a thickness smaller than the thickness of portion 22b. Preferably, the thickness of portion 22b is at least one and a half time greater than the thickness of portion 22a, for example, at least twice greater. The thickness of portion 22a is preferably constant. Similarly, the thickness of portion 22b is preferably constant.

Portions 22a and 22b preferably have a common and planar lower surface. Said lower surface is preferably in contact with body 12. The upper surfaces of portions 22a and 22b, that is, the surfaces opposite to the lower surface, are preferably parallel to each other.

Portion 22a preferably entirely covers region 20. Portion 22a at least partially, preferably partially, covers region 18. Region 18 is for example in contact with an entire peripheral portion of portion 22a, more precisely with the lower surface of the peripheral portion of layer 22. Region 22b for example partially covers region 18. Region 22b for example entirely covers the peripheral portion of region 18. Region 18 is for example entirely covered with portion 22a and portion 22b. Portion 22a preferably only rests on regions 18 and 20. Portion 22b for example partially covers region 14. Preferably, at least a portion of region 14 is not covered with layer 22.

Layer 22 is covered, preferably entirely, with a layer 24. Layer 24 is made of a conductor or semiconductor material, for example, of polysilicon. Layer 24 preferably only covers layer 24. Thus, the lateral walls of layer 24 are for example coplanar with the lateral walls of layer 22, that is, the lateral walls of portion 22b. Layer 24 is for example in contact with the entire upper surface of layer 24. Layer 24 is separated from body 12 by layer 22. Thus, layer 24 is not in contact with layer 12.

Cell 10 further comprises spacers 26 covering the lateral walls of layers 22 and 14. The spacers preferably cover all the lateral walls of layers 22 and 24. Preferably, at least a portion of region 14 is not covered with layer 22 or spacers 26.

Cell 10 comprises conductive vias, or contacts, 28. Region 14 is in contact with at least one via 28. In the example of FIGS. 1 to 3, region 14 is in contact with two vias 28. Layer 24 is in contact with at least one via 28, for example, a single via 28.

Preferably, the distance between two points of portion 22b separated by portion 22a is at least equal to 1.5 μm. For example, the distance between two points of region 18 separated by portion 20 is at least equal to 0.5 μm. Thus, the smallest dimension, in the plane of the upper surface of body 12, of the portion of portion 22a opposite region 18 is for example at least equal to 0.5 μm.

The ratio of the width of portion 22b to the width of portion 22a is for example greater than or equal to 2. In other words, the width of portion 22b is at least twice greater than the width of portion 22a. By width of portion 22b, there is meant the distance between the outer lateral wall of portion 22b, that is, the lateral wall most distant from portion 22a, and the inner lateral wall, that is, the interface between portions 22a and 22b. By width of portion 22a, there is meant the distance between two lateral walls of portion 22a in the plane where the width of portion 22b is measured.

During a memory cell programming step, a current flows through the cell between layer 24 and region 14, through layer 22 and region 18. The value of the current is sufficiently high to crack, or to break, the material of layer 22, that is, to damage it, preferably only in one location. Thus, in said location, the material of layer 22 is no longer electrically insulating.

To determine the data stored by the cell, the resistance between layer 24 and region 14 is for example determined. The memory cell is considered as storing a first binary value if the resistance is high, for example, greater than a threshold, which corresponds to the case where the material of layer 22 has not been cracked, and a second binary value if the resistance is low, for example, smaller than the threshold, which corresponds to the case where the material of layer 22 has been cracked.

In the embodiment of FIGS. 1 to 3, the break in the material of layer 22 appears in the portion of portion 22a opposite region 18. Indeed, the break appears on the path most accessible to the current, that is, the least resistive path. The path crossing the portion of portion 22a opposite region 20 has a resistance greater than that of the path crossing the portion of portion 22a opposite region 18, region 20 being less heavily doped than region 18. The path crossing the portion of portion 22b opposite region 18 or region 14 has a resistance greater than that of the path crossing the portion of portion 22a opposite region 18, portion 22b being thicker than portion 22a.

It is thus possible to anticipate the location of the break. Further, the location is substantially in the same portion of layer 22 whatever the memory cell.

It could have been chosen to form a planar layer 22, that is, having a constant thickness across its entire surface. However, it would not have been possible to anticipate the location of the break. The breaks could then be located at different locations of the insulator layer, which would cause a variability from one cell to another in the threshold value between the first and second binary values.

Further, during the cell manufacturing method, various steps may damage layer 22, and more particularly the periphery of layer 22. For example, the steps capable of causing damage to layer 22 include the substrate doping steps, the spacer forming, the etching of layer 24, etc. The damage caused is not identical in all memory cells. Thus, if layer 22 is a planar layer, the breaks may occur at the periphery of layer 22 and cause variations of the threshold value.

Various embodiments and variants have been described. Those skilled in the art will understand that certain features of these various embodiments and variants may be combined, and other variants will occur to those skilled in the art. In particular, although regions 14, 18, 20 and layers 22, 24 have in top view substantially rectangular shapes, it should be understood that regions 14, 18, 20 and layers 22, 24 may have, in top view, other shapes, for example, circular, oval shapes or quadrilateral shapes with rounded angles.

Finally, the practical implementation of the described embodiments and variations is within the abilities of those skilled in the art based on the functional indications given hereabove.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A cell comprising:
a first insulating layer located between a semiconductor body and a second conductive or semi-conductive layer,
wherein the first insulating layer comprises a peripheral portion and a central portion,
wherein the peripheral portion has a greater thickness than the central portion, and
wherein the cell is a programmable read-only memory.

2. The cell according to claim 1, wherein the semiconductor body is in direct contact with the first layer, and wherein the second layer is in direct contact with the first layer.

3. The cell according to claim 1, wherein the semiconductor body and the second layer are not in direct contact with each other.

4. The cell according to claim 1, wherein a thicknesses of the central portion is substantially constant, and wherein a thickness of the peripheral portion is substantially constant.

5. The cell according to claim 1, wherein a thickness of the peripheral portion is at least one and a half times greater than a thickness of the central portion.

6. The cell according to claim 1, wherein the semiconductor body comprises a first region and a second region, the second region being more heavily doped than the first region, and wherein the central portion is in direct contact with the second region.

7. The cell according to claim 6, wherein the second region surrounds a portion of the first region, the central portion only resting on the second region and on the portion of the first region.

8. The cell according to claim 6, wherein a peripheral portion of the second region is covered with the peripheral portion.

9. The cell according to claim 6, wherein a portion of the second region, which is not covered with the central portion, is covered with the peripheral portion.

10. The cell according to claim 6, wherein a dopant concentration of the second region is at least twice as much as a dopant concentration of the first region.

11. The cell according to claim 6, wherein a smallest dimension of a portion of the central portion located opposite the second region is at least equal to 0.5 μm.

12. The cell according to claim 6, wherein the semiconductor body further comprises a third region, wherein the third region is more heavily doped than the second region, wherein the third region surrounds the second region, and wherein the third region comprises at least a portion that is not covered with the first layer.

13. The cell according to claim 12, further comprising at least one conductive contact in direct contact with the third region.

14. The cell according to claim 1, wherein a ratio between a width of the peripheral portion and a width of the central portion is greater than or equal to 2.

15. The cell according to claim 1, wherein the second layer covers only the first layer.

16. A cell comprising:
a semiconductor body comprising an upper surface, a lower surface, a side surface, two first doped regions and two second doped regions, wherein each of the first doped regions extends more from the upper surface to the lower surface than each of the second doped regions, and wherein the first doped regions are closer to the side surface than the second doped regions;
a first insulating layer arranged directly on the semiconductor body the first insulating layer comprising a peripheral portion and a central portion; and
a second conductive or semi-conductive layer arranged directly on the first insulating layer,
wherein the peripheral portion has a greater thickness than the central portion,
wherein the peripheral portion is in direct contact with the first and second doped regions,
wherein the central portion is in direct contact with the semiconductor body and the second doped regions but not with the first doped regions, and
wherein the cell is a programmable read-only memory.

17. The cell according to claim 16, wherein a thicknesses of the central portion is substantially constant, and wherein a thickness of the peripheral portion is substantially constant.

18. The cell according to claim 16, wherein a thickness of the central portion is at least equal to 0.5 μm.

19. The cell according to claim 16, wherein a ratio between a width of the peripheral portion and a width of the central portion is greater than or equal to 2.

20. The cell according to claim 16, further comprising:
a spacer arranged on the first regions and covering side surfaces of the first and second layers;
first vias directly contacting the first regions; and
a second via directly contacting the second layer.
